(19) United States
(12) Patent Application Publication
(10) Pub. No.: US 2014/0069491 A1
(43) Pub. Date: Mar. 13, 2014

(54) Interposer Connector for High Power Solar Concentrators

(71) Applicants: Ayman Alabduljabbar, Riyadh (SA); Abdullah I. Alboiez, Riyadh (SA); Yaseen G. Alharbi, Riyadh (SA); Alhassan Badahdah, Riyadh (SA); Supratik Guha, Chappaqua, NY (US); Theodore Gerard vanKessel, Millbrook, NY (US); Hussam Khonkar, Riyadh (SA); Yves C. Martin, Ossining, NY (US); Naim Moumen, Walden, NY (US); Robert L. Sandstrom, Chestnut Ridge, NY (US)

(72) Inventors: Ayman Alabduljabbar, Riyadh (SA); Abdullah I. Alboiez, Riyadh (SA); Yaseen G. Alharbi, Riyadh (SA); Alhassan Badahdah, Riyadh (SA); Supratik Guha, Chappaqua, NY (US); Theodore Gerard vanKessel, Millbrook, NY (US); Hussam Khonkar, Riyadh (SA); Yves C. Martin, Ossining, NY (US); Naim Moumen, Walden, NY (US); Robert L. Sandstrom, Chestnut Ridge, NY (US)

(73) Assignees: King Abdulaziz City for Science and Technology, Riyadh (SA); International Business for High Power Solar Concentrators, Armonk, NY (US)

(21) Appl. No.: 13/614,080

(22) Filed: Sep. 13, 2012

(51) Int. Cl. H01L 31/0232; H01L 31/024; H01L 31/06

(52) U.S. Cl. 136/255; 136/259

(57) ABSTRACT

In one aspect, an interposer assembly for housing a photovoltaic device includes a frame, formed from an electrically insulating material, having a center opening with a shape/size complementary to a shape/size of the photovoltaic device thus permitting the photovoltaic device to fit within the center opening in the frame when the photovoltaic device is housed in the assembly; a beam shield on the frame having a cup-shaped inner cavity to aid in routing of light to the photovoltaic device, wherein a side of the beam shield facing the frame has one or more recesses present therein; and one or more interposer connectors positioned between the frame and the beam shield such that the interposer connectors fit within the recesses in the beam shield, and wherein a portion of each of the interposer connectors extends into the center opening of the frame.

### FIELD OF THE INVENTION

The present invention relates to concentrated photovoltaic devices, and more particularly, to techniques for providing high-capacity, re-workable connections in concentrated photovoltaic devices.

### BACKGROUND OF THE INVENTION

Solar concentrators operate by focusing light to a spot on a photovoltaic cell. The concentrated spot of light enables a small semiconductor to operate at higher power density levels than would be possible in flat solar panels without optical concentration. By using optical concentration, it is possible to construct a photovoltaic system using less semiconductor material, thus desirably lowering production costs.

As a result of optical concentration, the photovoltaic cell produces electric power at high current and with a significant heat load. Thus, measures must be employed to thermally shield the electrical connections and other sensitive components surrounding the photovoltaic cell from the focused light beam. Provisions must also be made to remove the heat load, for which a heat sink is commonly employed. Finally at high concentrations, a significant amount of current must be efficiently conveyed from the cell to the remaining circuitry with minimal electrical resistance.

In order to allow the series connection of concentrated photovoltaic devices (which is often desired), the semiconductor materials of the cells must be electrically insulated from the heat sink materials. Electrically insulating the cells from the heat sink also allows operators to handle the devices without risk of electric shock. This electrical insulation is usually accomplished by attaching each photovoltaic cell to a ceramic or composite plastic substrate on which top surface metal connection pads are provided.

Standard connectors and cables exist for external connections that are capable of carrying both high current and high voltage direct current (DC) electricity to/from the photovoltaic cells. It is often necessary to make connections using these standard connectors (which are often physically large) to the photovoltaic cell directly or indirectly via the photovoltaic cell substrate. In the case of non conducting substrates, this is usually done by printing copper lines to convey the current. One method used in the field is to solder both pin and socket connectors directly on the substrate (package). This practice, however, imposes considerable strain on the substrate material and coatings. Coatings include plated copper lines on the substrate which under stress can peel up and fail. Further, the substrate is often thin and made of ceramic. In addition this method may restrict the number of contact points through which a large amount of current will be passed.

The combination of cell, substrate, connections and heat sink are typically referred to as a solar receiver. The solar receiver is often assembled into a module. The components used to construct concentrated solar receivers are expensive. Further, it is desirable to be able to re-work or replace receiver components in the field. To this end it is desirable to avoid soldering and other complex process operations.

Therefore, techniques for providing high-capacity connections in concentrated photovoltaic devices which are re-workable, preferably in the field, would be desirable.

### SUMMARY OF THE INVENTION

The present invention provides techniques for providing high-capacity, re-workable connections in concentrated photovoltaic devices. In one aspect of the invention, an interposer assembly for housing a photovoltaic device is provided. The interposer assembly includes a frame formed from an electrically insulating material, wherein the frame has a center opening with a shape and a size complementary to a shape and a size of the photovoltaic device thus permitting the photovoltaic device to fit within the center opening in the frame when the photovoltaic device is housed in the assembly; a beam shield on the frame having a cup-shaped inner cavity to aid in routing of light to the photovoltaic device when the photovoltaic device is housed in the assembly, wherein a side of the beam shield facing the frame has one or more recesses present therein; and one or more interposer connectors positioned between the frame and the beam shield such that the interposer connectors fit within the recesses in the beam shield, and wherein a portion of each of the interposer connectors extends into the center opening of the frame thus permitting the interposer connectors to contact the photovoltaic device when the photovoltaic device is housed in the assembly.

In another aspect of the invention, a photovoltaic apparatus is provided. The photovoltaic apparatus includes an interposer assembly; and a photovoltaic device housed in the interposer assembly. The interposer assembly includes a frame formed from an electrically insulating material, wherein the frame has a center opening with a shape and a size complementary to a shape and a size of the photovoltaic device, and wherein the photovoltaic device is positioned with the center opening of the frame; a beam shield on the frame having a cup-shaped inner cavity to aid in routing of light to the photovoltaic device, wherein a side of the beam shield facing the frame has one or more recesses present therein; and one or more interposer connectors positioned between the frame and the beam shield such that the interposer connectors fit within the recesses in the beam shield, wherein a portion of each of the interposer connectors extends into the center opening of the frame and contacts the photovoltaic device.

A more complete understanding of the present invention, as well as further features and advantages of the present invention, will be obtained by reference to the following detailed description and drawings.

### BRIEF DESCRIPTION OF THE DRAWINGS

FIG. 1 is a three-dimensional diagram illustrating an interposer assembly for a concentrating photovoltaic device having a beam shield and a plurality of connectors according to an embodiment of the present invention;

FIG. 2 is a three-dimensional diagram illustrating a top orientation of the interposer assembly and its relation to other photovoltaic device components according to an embodiment of the present invention;

FIG. 3 is a three-dimensional diagram illustrating a bottom orientation of the interposer assembly and its relation to other photovoltaic device components according to an embodiment of the present invention;

FIG. 4 is a three-dimensional diagram illustrating how the interposer assembly makes contact with connector pads on a photovoltaic insulating package and the relative position of the beam shield from a top orientation according to an embodiment of the present invention; and

FIG. 5 is a cross-sectional diagram illustrating an exemplary triple junction photovoltaic cell according to an embodiment of the present invention.

### DETAILED DESCRIPTION OF PREFERRED EMBODIMENTS

Provided herein are interposer assemblies for housing concentrating photovoltaic devices that include field re-workable electrical connections that are mechanically strain relieved and provide many contact points to enable redundant high current capability. In the following description and accompanying drawings the same structures and components are numbered alike.

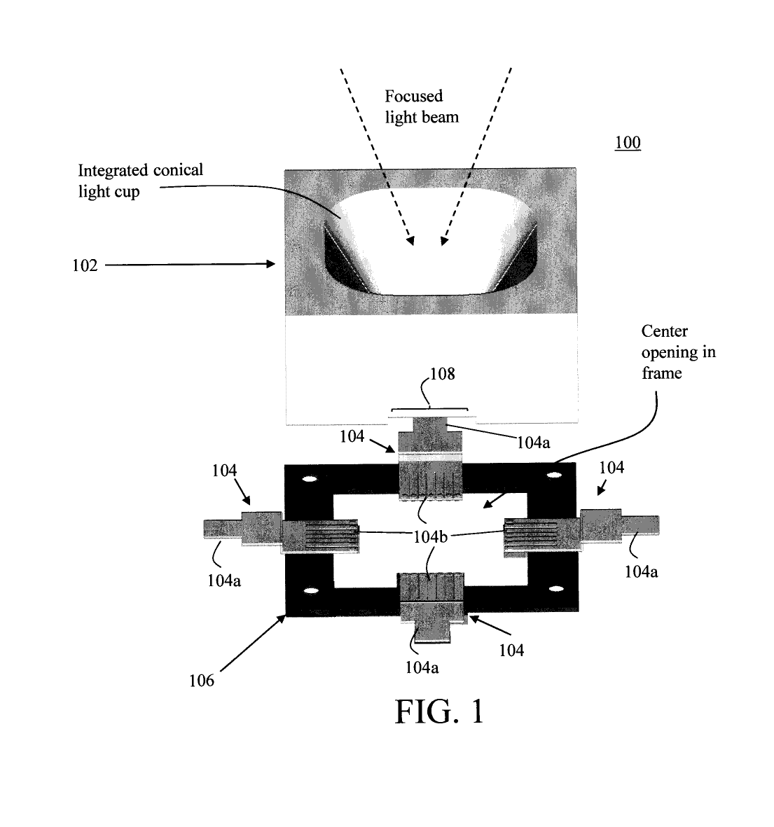

FIG. 1, for example, is a three-dimensional diagram illustrating an interposer assembly 100 for housing a concentrating photovoltaic device. Interposer assembly 100 includes a beam shield 102 and a plurality of interposer connectors 104 (for providing connection to the photovoltaic device) affixed/attached to an electrically insulating frame 106 (i.e., the frame is formed from an electrically insulating material).

The interposer connectors 104 may be affixed to the frame 106 using an adhesive. Suitable adhesives include, but are not limited to, epoxy adhesives and/or high temperature adhesives, e.g., polyimide-based adhesives.

Alternatively, the interposer connectors 104 may be solder attached to the frame 106. Specifically, according to an exemplary embodiment, the frame 106 includes a plated metal pattern thereon (not shown). As would be apparent to one of skill in the art, the metal pattern can be plated on the frame 106 using standard metal plating techniques. By way of example only, copper can be plated on the frame 106. The interposer connectors can then be solder attached to the metal pattern. Suitable solders include, but are not limited to, tin-lead (PbSn) eutectic solder and/or a tin-silver-copper (SnAgCu) (SAC) solder.

Beam shield 102 serves to thermally shield interposer connectors 104 and other sensitive components associated with the photovoltaic device from the focused light beam. See FIG. 1. Specifically, the purpose of the beam shield 102 is to prevent the high energy density focused beam from damaging sensitive components adjacent to the solar cell in cases when the beam moves off of the cell. In the example shown illustrated in FIG. 1, the beam shield 102 is configured to have a conical (cup-shaped) inner cavity (also referred to herein as an integrated light cup) to aid in the routing of the beam to the cell during off axis transients or a partially focused beam. The beam shield 102 is constructed to reject as much radiation as possible and to dissipate any absorbed heat.

A wide variety of materials may be used to form the beam shield 102. By way of example only, the beam shield 102 may be formed from a variety of metals and alloys. Suitable metals and alloys include, but are not limited to, aluminum, copper, iron, steel, magnesium, tin, titanium, chrome, nickel, stainless steel, and alloys containing at least one of the foregoing metals.

In one exemplary embodiment, the beam shield 102 is made of aluminum. Alternatively, in another exemplary embodiment, the beam shield 102 is formed from a sheet metal, such as a sheet of steel, which can be stamped or otherwise formed into the shape of the beam shield 102 shown in FIG. 1.

As shown in FIG. 1, each interposer connector 104 includes a lug connector 104a that is electrically and mechanically joined to one or more finger spring contacts 104b. According to an exemplary embodiment, the lug connector 104a and the finger spring contacts 104b of each interposer connector 104 are formed from a single piece of conductive, and mechanically stiff material. Suitable materials for forming the interposer connector 104 include a metal(s) such as aluminum, brass, steel, iron, magnesium, copper and alloys thereof (e.g., beryllium copper). Further, in some embodiments, gold plating of the interposer connectors 104 is used to promote good electrical contact and prevent oxidation of the contacts. Alternatives to gold include other noble metals including silver, palladium gold and platinum. Thus, in one exemplary configuration, the interposer connectors 104 are composed of gold plated beryllium copper.

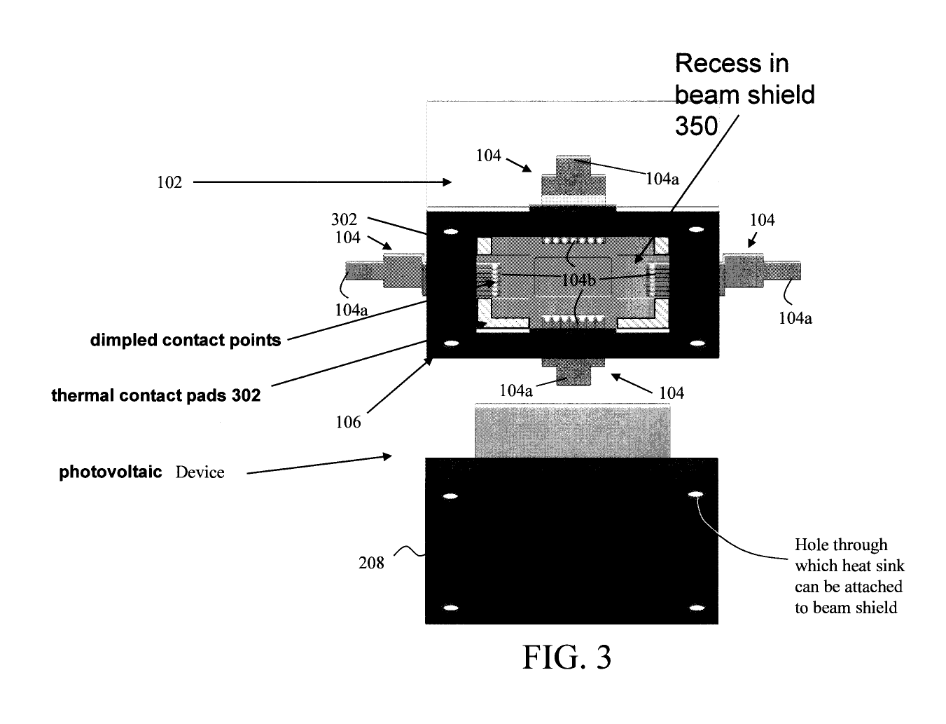

Alternatively, the interposer connectors 104 may be constructed from multiple pieces of metal arranged to make good electrical contact and mechanical strain relief. See, for example, the description of FIG. 3, below.

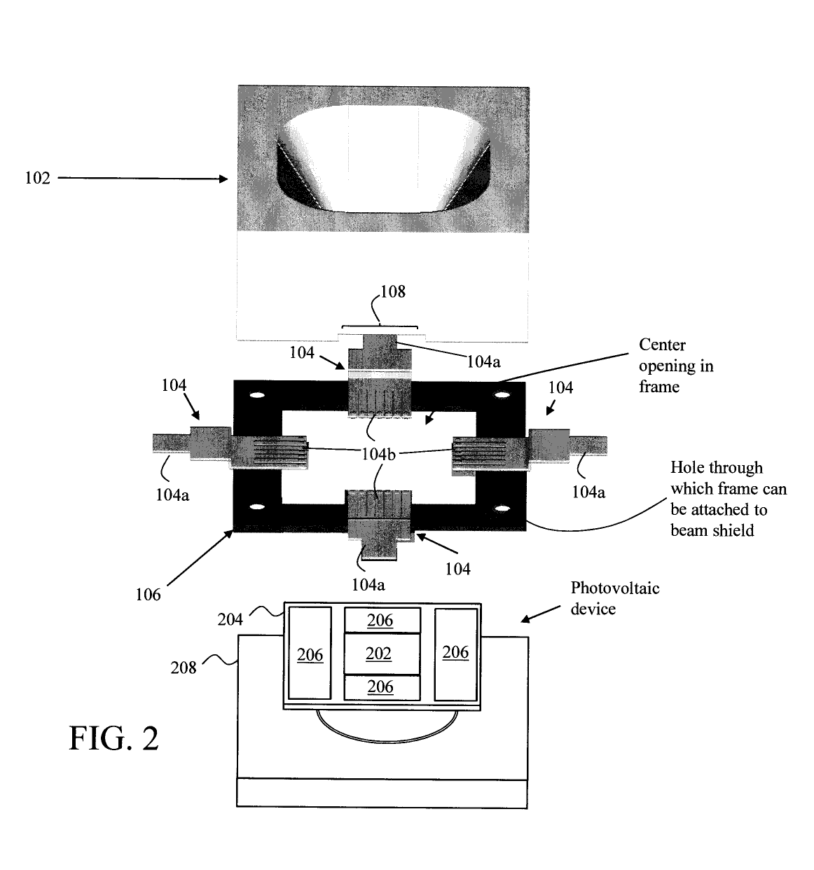

The interposer connectors 104 are affixed to the electrically insulating frame 106 (e.g., by way of a solder or adhesive bond, see above) for mechanical support and both thermal and electrical insulation. According to an exemplary embodiment, the electrically insulating frame 106 is made of plastic or a composite material, such as fiberglass. These are materials which are both thermally and electrically isolating/insulating and also provide mechanical support for the interposer connectors 104. The depiction in FIG. 1 of the electrically insulating frame 106 having an overall square shape is merely exemplary. Further, the electrically insulating frame 106 has a center opening (see FIG. 1) in which a photovoltaic device can fit when a photovoltaic device is housed in the assembly (see below). Thus, the center opening in the electrically insulating frame 106 should have a shape and size that compliments a shape and size of the photovoltaic device. Of course, the shape and/or size of the photovoltaic device can vary, and thus is application-specific. By way of example only, the photovoltaic device presented in the exemplary embodiment below (see, for example, FIG. 2, described below) has a square shape. Thus, in that case, the center opening in the electrically insulating frame 106 would also have a square shape. The size of the center opening in the electrically insulating frame 106 should be slightly larger than the size of the photovoltaic device, so as to permit the photovoltaic device to fit within the frame. The tolerance between the center opening and the photovoltaic device can be configured so as to prevent lateral movement of the photovoltaic device once housed in the assembly (see below). One of ordinary skill in the art, given the present teachings, would be able to easily ascertain the desired size of the center opening given a certain photovoltaic device size. For instance, making the center opening from about one percent to about five percent larger than the outer dimensions of the photovoltaic device would be suitable.

In the exemplary embodiment shown in FIG. 1, the interposer assembly includes four interposer connectors 104. Multiple connections reduce the contact resistance (an important parameter in concentrating solar applications due to the high current) and to further improve reliability through multiple redundant connections. More/fewer interposer connectors may be employed depending on the particular application at hand.

As shown in FIG. 1, the beam shield 102 has recesses 108 on a bottom surface thereof, i.e., the recesses 108 are on a side of the beam shield 108 facing the electrically insulating frame 106 (see FIG. 1). Only one such recess 108 is visible in the viewpoint depicted in FIG. 1, however it is preferable that multiple recesses 108 are present, e.g., one recess for each of the interposer connectors 104. According to an exemplary embodiment, the recesses 108 are notches or cut-outs of the beam shield that are a negative impression of the shape of a part of the interposer connectors 104 which the beam shield 102 covers. Namely, when the interposer assembly houses a photovoltaic device (see below), the recesses 108 mate with the interposer connectors 104 and serve to mechanically constrain (so as to prevent movement of) the electrically insulating frame 106/interposer connectors 104 and thus to locate the electrically insulating frame 106/interposer connectors 104 relative to the photovoltaic device.

When assembled with a photovoltaic device, the interposer connectors 104 are positioned between the electrically insulating frame 106 and the beam shield 102. Further, as shown in FIG. 1, a portion of each of the interposer connectors 104 (e.g., the finger spring contacts 104b) extend into the center opening of the electrically insulating frame 106 which permits the interposer connectors 104 to contact the photovoltaic device when the photovoltaic device is fit within the center opening (see, for example, FIG. 3, described below). Thus, the interposer connectors 104 provide high capacity electrical connections to the photovoltaic device. See, for example, FIG. 2.

FIG. 2 is a three-dimensional diagram illustrating a top orientation of interposer assembly 100 and its relation to other photovoltaic device components. The interposer assembly 100 and photovoltaic device are also collectively referred to herein as a “photovoltaic apparatus.” According to this exemplary embodiment, the photovoltaic device components include a photovoltaic cell 202 on an electrically insulating wafer 204 (also collectively referred to herein as a “photovoltaic insulating package”), contact pads 206 to photovoltaic cell 202 on the insulating wafer, and heat sink 208 (also referred to herein as a “heat sink spreader”) in thermal contact with insulating wafer 204.

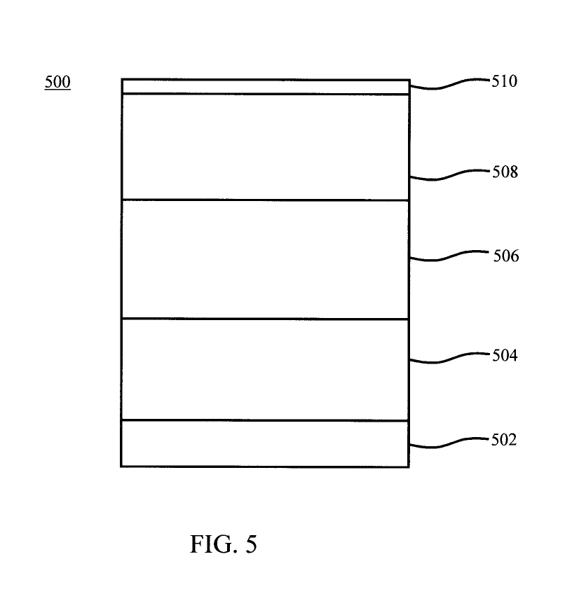

According to an exemplary embodiment, photovoltaic cell 202 is a multi junction photovoltaic cell. An exemplary multi junction photovoltaic cell is shown in FIG. 5, described below.

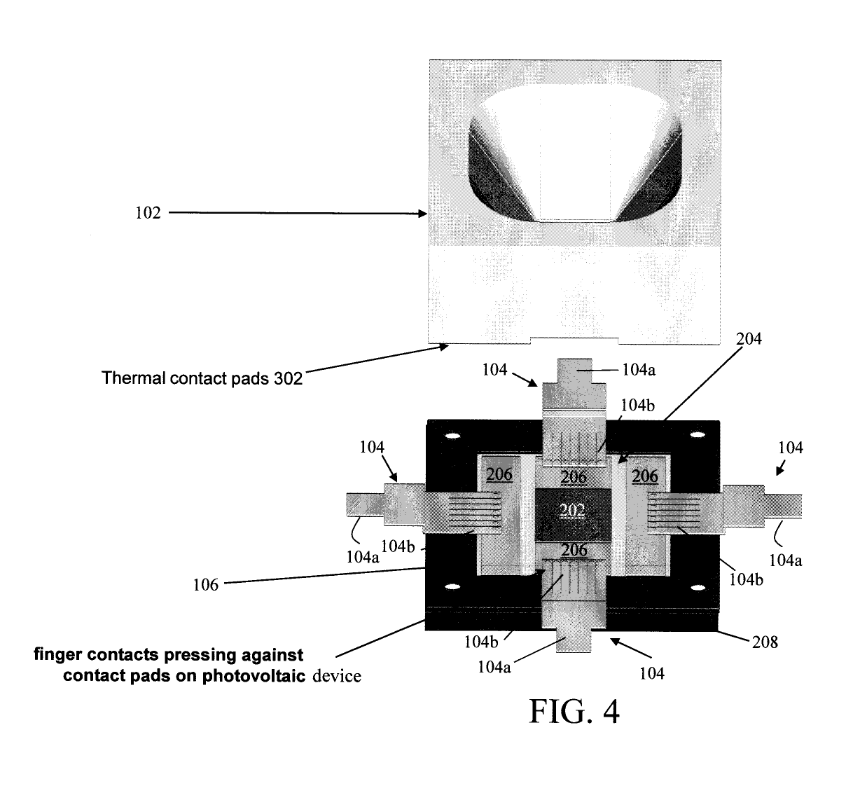

The electrically insulating wafer 204 may be formed from any suitable electrically insulating material that also provides mechanical support for the photovoltaic cell 202 and the contact pads 206 thereon. Suitable materials for forming the wafer 204 include, but are not limited to, ceramic, aluminum oxide, aluminum nitride, sapphire, plastic or a composite material, such as fiberglass, carbon fiber, carbon nanofiber composite or laminated materials. In general it is also desirable that the insulating wafer 204 be thermally conductive and attached to a heat sink (e.g., heat sink 208) via a thermal interface material (see, for example, the description of FIG. 4, below).

The photovoltaic cell 202 is affixed to the insulating wafer 204. The photovoltaic cell may be attached directly to the insulating wafer 204 using an adhesive. Suitable adhesives include, but are not limited to, epoxy adhesives and/or high temperature adhesives, e.g., polyimide-based adhesives. The photovoltaic cell 202 may alternately be affixed to a thermally conducting pad (not shown) on the insulating wafer 204 using a solder adhesive. Examples of solder adhesives include, but are not limited to, lead tin solder (PbSn) and low melt solders such as SnAgCu. By way of example only, the thermally conducting pad (formed, e.g., from a metal such as copper) can be affixed to the insulating wafer 204 using one of the above described adhesives, and the photovoltaic cell 202 can be solder-attached to the thermally conducting pad. In this example, the placement/positioning of the photovoltaic cell 202 relative to the insulating wafer 204 would be the same as that illustrated in FIG. 2, except in this case there would be a thermally conducting pad therebetween.

The contact pads 206 may be affixed to the surface of the wafer 204, for example, using an adhesive. Suitable adhesives include, but are not limited to, epoxy adhesives and/or high temperature adhesives, e.g., polyimide-based adhesives.

The contact pads 206 may be formed from an electrically conductive material, such as a metal(s). Suitable metals include, but are not limited to beryllium copper. Further, in some embodiments, gold plating of the contact pads 206 is used to promote good electrical contact and prevent oxidation of the contacts. Alternatives to gold include other noble metals including silver, palladium gold and platinum. Thus, in one exemplary configuration, the contact pads 206 are composed of gold plated beryllium copper.

The heat sink 208 may be made from aluminum. Other suitable heat sink materials include, but are not limited to, copper. While copper is a better thermal conductor than aluminum, to reduce the overall weight of the device, aluminum might be preferable.

When assembled, the finger spring contacts 104b of the interposer connectors 104 make physical and electrical contact with (are pressed against) the contact pads 206. This contact scheme is illustrated in further detail in FIG. 4, described below.

As shown in FIG. 2, the photovoltaic device has an outer dimension (in this case based on the outer dimensions of the electrically insulating wafer 204) that is complementary to the center opening in the electrically insulating frame 106 (see above description of center opening size/shape and photovoltaic device size/shape). Thus, the insulating wafer 204 can fit within the center opening in the electrically insulating frame 106 (see also FIG. 4, described below) and the electrically insulating frame 106 will laterally constrain (i.e., prevent the lateral movement of) the electrically insulating wafer 204 (and the photovoltaic cell 202 affixed thereto). Thus, since the interposer connectors 104 are affixed to the electrically insulating frame 106 (see above), then constraining the electrically insulating wafer 204 within the electrically insulating frame 106 will serve to center the interposer connectors 104 (i.e., the finger spring contacts 104b of the interposer connectors 104) on the contact pads 206. In this exemplary embodiment, there are four interposer connectors 104 and four contact pads 206, with one interposer connector corresponding to each one of the contact pads.

The electrically insulating frame 106 (with the interposer connectors 104) may be affixed/attached to the beam shield 102 using any suitable mechanical connectors or bonding agents. According to an exemplary embodiment, the electrically insulating frame 106 is affixed to the beam shield 102 using a mechanical fastener through a hole(s) provided in the bottom of the beam shield 102 and the electrically insulating frame 106. See, for example, FIG. 2. In one exemplary embodiment the mechanical fastener is a screw. Further, a corresponding hole(s) in the heat sink 208 may be present to allow the heat sink to be attached (through the electrically insulating frame 106) to the beam shield 102. Thus, a mechanical fastener, such as a screw(s), can pass through the hole(s) in the beam shield 102, the electrically insulating frame 106 and the heat sink 208 that line up when these components are assembled. The result is a mechanically solid assembly. It is important, however, to make sure to avoid short circuit contacts with energized components when configuring the number, size and placement of the attaching holes and fasteners.

FIG. 3 is a three-dimensional diagram illustrating another orientation, i.e., a bottom orientation, of the interposer assembly 100 and its relation to other photovoltaic device components. As shown in FIG. 3, the beam shield 102 has a recess 350 machined into a bottom surface thereof that accommodates the photovoltaic insulating package and the interposer connectors 104.

As also shown in FIG. 3, each of the finger spring contacts 104b preferably has dimpled contact points at the end of each “finger.” These dimpled contact points ensure proper contact with the photovoltaic insulating package/contact pads. Use of dimpled contact points on electrical connectors to ensure that proper physical and electrical contact is made is known to those of skill in the art and thus is not described further herein.

As highlighted above, in one exemplary embodiment, the lug connections 104a and finger spring contacts 104b of each interposer connector 104 are formed from a single metal that is plated with a noble metal, such as gold, silver, palladium gold and platinum, to ensure corrosion free operation and good electrical contact. However, as highlighted above, the interposer connectors can be constructed from multiple metals. Namely, the base material for lug connections 104a and finger spring contacts 104b can vary depending on the application. According to an exemplary embodiment, the base material for lug connections 104a is or more of aluminum, brass, steel, iron, magnesium, copper and alloys thereof. It is notable that a variety of suitable metals exist, and those being mentioned here are merely exemplary. In general the lug metal is chosen for low cost, durability and malleability. Gold plating or other suitable metal plating (see other suitable noble metals listed above) may be used for improving corrosion resistance and contact resistance. For example, lug connections 104a can be gold plated aluminum, brass or copper. The base material for finger spring contacts 104b may be beryllium copper. For example, finger spring contacts 104b may be gold plated beryllium copper. As mentioned above, the finger spring contact 104b base metal is chosen from metals that are stiff (springy). The finger spring contacts 104b may be plated as described above to improve contact resistance and corrosion resistance.

As shown in FIG. 3, in one exemplary embodiment thermal contact pads 302 may be employed between the beam shield 102 and the electrically insulating frame 106/the heat sink 208 to make thermal contact with the heat sink 208. The thermal contact pads 302 further mechanically locate the insulating wafer 204 and the electrically insulating frame 106 in this embodiment. By way of example only, the thermal contact pads 302 can be both physically and thermally in contact with the beam shield 102 and both physically and thermally in contact with the heat sink 208. Alternatively, in the embodiment shown in FIGS. 3 and 4, the thermal contact pads 302 are in physically and thermally in contact with the beam shield 102 and are physically and thermally in contact with the contact pads 206. In this embodiment, the contact pads 206 convey heat absorbed in the beam shield 102 (through the thermal contact pads 302) to the heat sink 208. Thus, in this case, while the thermal contact pads 302 are in thermal contact with the heat sink 208, the thermal contact pads 302 are not in physical contact with the heat sink 208.

A variety of embodiments are possible for the beam shield 102. Ultimately, the beam shield 102 must radiate, or convect the absorbed heat to either the air surrounding it or to the heat sink 208. In the exemplary embodiment shown, the heat sink 208 is chosen to receive the heat from the beam shield 102 by way of the thermal contact pads 302 which perform the additional function of physically constraining the insulating wafer 204 and the electrically insulating frame 106. Thus, the beam shield is in thermally conductive contact with the heat sink to promote the flow of heat.

FIG. 4 is a three-dimensional diagram illustrating how the interposer assembly 100 makes contact with the contact pads 206 on the photovoltaic insulating package and the relative position of the beam shield 102 from a top orientation. FIG. 4 illustrates the relative position of the finger spring contacts 104b relative to contact pads 206 on the photovoltaic insulating package when fully assembled. In this embodiment, the dimpled contact points on the end of the “fingers” of finger spring contacts 104b are pressed against the corresponding contact pads 206 on electrically insulating wafer 204. See, FIG. 4.

A further attribute of the embodiments shown is that when fully assembled the finger spring contacts 104b press the insulating wafer 204 against the heat sink 208. During operation, heat must be removed from both the beam shield 102 and the insulating wafer 204. In the embodiment shown in FIG. 4, the beam shield 102 contacts the contact pads 302 which make mechanical and thermal contact with heat sink 208. Electrically insulating wafer 204 makes thermal and mechanical contact with the heat sink 208.

In one embodiment, the thermal contact between the electrically insulating wafer 204 and the heat sink 208 is enhanced using a thermal interface material. A thermal interface material may also be used in between the beam shield 102 and the heat sink 208 so as to enhance the thermal contact between the beam shield 102 and the heat sink 208. By way of example only, the thermal interface material may be used instead of, or in addition to, the thermal contact pads 302. As described above, the thermal contact pads 302 serve to conduct heat from the beam shield 102 to the heat sink 208, either directly, or through contact pads 206. Thus, the thermal contact pads 302 may simply be replaced with a thermal interface material between the beam shield 102 and the heat sink 208 or between the beam shield 102 and the contact pads 206. The thermal interface material might also be placed on the surfaces of the thermal contact pads 302 so as to enhance heat transfer between the beam shield 102 and the heat sink 208.

A thermal interface material increases heat transfer efficiency by increasing thermal contact between the respective surfaces. Suitable thermal interface materials include, but are not limited to, thermal grease such as Krytox® grease (available from E.I. du Pont de Nemours and Company, Wilmington, Del.), a conductive particle infused thermal grease, a liquid metal, a conductive particle infused gel and a solid soft metal alloy (such as a lead- or gold-containing alloy).

Since the components of the interconnector assembly are unitized and non-permanently attached to one another, the present package designs are field re-workable/replaceable. This re-workable configuration is beneficial since the components comprising the receiver are expensive. To the extent that sub components of the receiver can be replaced during the service life of the solar system, costs can be saved.

FIG. 5 is a diagram illustrating a cross-sectional view of exemplary triple junction photovoltaic cell 500. Triple junction photovoltaic cell 500 represents one possible configuration of photovoltaic cell 202. Triple-junction photovoltaic cell 500 comprises substrate 502, photovoltaic cells 504, 506 and 508 and anti-reflective coating 510. According to an exemplary embodiment, substrate 502 comprises a germanium (Ge) substrate and has a thickness of about 200 micrometers (μm). A photovoltaic cell, such as triple junction photovoltaic cell 500, can have an overall thickness of less than about one millimeter (mm).

Photovoltaic cell 504 may be separated from photovoltaic cell 506 by a tunnel diode (not shown). Similarly, photovoltaic cell 506 may be separated from photovoltaic cell 508 by a tunnel diode (not shown). Each of photovoltaic cells 504, 506 and 508 should be configured such that, collectively, photovoltaic cells 504, 506 and 508 absorb as much of the solar spectrum as possible. By way of example only, photovoltaic cell 504 can comprise Ge, photovoltaic cell 506 can comprise gallium arsenide (GaAs) and photovoltaic cell 508 can comprise gallium indium phosphide (GaInP).

Although illustrative embodiments of the present invention have been described herein, it is to be understood that the invention is not limited to those precise embodiments, and that various other changes and modifications may be made by one skilled in the art without departing from the scope of the invention.

What is claimed is:

1. An interposer assembly for housing a photovoltaic device, comprising:
a frame formed from an electrically insulating material, wherein the frame has a center opening with a shape and a size complementary to a shape and a size of the photovoltaic device thus permitting the photovoltaic device to fit within the center opening in the frame when the photovoltaic device is housed in the assembly;
a beam shield on the frame having a cup-shaped inner cavity to aid in routing of light to the photovoltaic device when the photovoltaic device is housed in the assembly, wherein a side of the beam shield facing the frame has one or more recesses present therein; and
one or more interposer connectors positioned between the frame and the beam shield such that the interposer connectors fit within the recesses in the beam shield, and wherein a portion of each of the interposer connectors extends into the center opening of the frame thus permitting the interposer connectors to contact the photovoltaic device when the photovoltaic device is housed in the assembly.

2. The interposer assembly of claim 1, wherein each of the interposer connectors comprises a lug connection joined to one or more finger spring contacts.

3. The interposer assembly of claim 2, wherein the lug connection is formed from one or more of gold plated aluminum, brass and copper.

4. The interposer assembly of claim 2, wherein the finger spring contacts are formed from gold plated beryllium copper.

5. The interposer assembly of claim 2, wherein the finger spring contacts are dimpled.

6. The interposer assembly of claim 1, wherein the interposer connectors are attached to the frame.

7. The interposer assembly of claim 1, wherein the interposer connectors are attached to the frame using an adhesive.

8. A photovoltaic apparatus, comprising:
an interposer assembly; and
a photovoltaic device housed in the interposer assembly, wherein the interposer assembly comprises:
a frame formed from an electrically insulating material, wherein the frame has a center opening with a shape and a size complementary to a shape and a size of the photovoltaic device, and wherein the photovoltaic device is positioned with the center opening of the frame;
a beam shield on the frame having a cup-shaped inner cavity to aid in routing of light to the photovoltaic device, wherein a side of the beam shield facing the frame has one or more recesses present therein; and
one or more interposer connectors positioned between the frame and the beam shield such that the interposer connectors fit within the recesses in the beam shield, wherein a portion of each of the interposer connectors extends into the center opening of the frame and contacts the photovoltaic device.

9. The apparatus of claim 8, wherein the photovoltaic device comprises:
a photovoltaic cell on a wafer formed from an electrically insulating material;
contact pads to the photovoltaic cell on the wafer; and
a heat sink in thermal contact with the wafer.

10. The apparatus of claim 9, wherein the frame laterally constrains the photovoltaic device and centers the interposer connectors on the contact pads.

11. The apparatus of claim 9, further comprising:
a thermal interface material between the heat sink and the wafer to enhance thermal contact between the heat sink and the wafer.

12. The apparatus of claim 11, wherein the thermal interface material comprises one or more of thermal grease, a conductive particle infused thermal grease, a liquid metal, a conductive particle infused gel and a solid soft alloy.

13. The apparatus of claim 9, wherein the beam shield is in thermal contact with the heat sink to promote heat flow.

14. The apparatus of claim 13, further comprising:
a thermal interface material between the beam shield and the heat sink to enhance thermal contact between the beam shield and the heat sink.

15. The apparatus of claim 14, wherein the thermal interface material comprises one or more of thermal grease, a conductive particle infused thermal grease, a liquid metal, a conductive particle infused gel and a solid soft alloy.

16. The apparatus of claim 9, wherein each of the interposer connectors comprises a lug connection joined to one or more finger spring contacts.

17. The apparatus of claim 16, wherein the lug connection is formed from one or more of gold plated aluminum, brass or copper.

18. The apparatus of claim 16, wherein the finger spring contacts are formed from gold plated beryllium copper.

19. The apparatus of claim 16, wherein the finger spring contacts are dimpled.

20. The apparatus of claim 16, wherein the finger spring contacts are pressed against the contact pads on the wafer.

21. The apparatus of claim 9, wherein the photovoltaic cell is a multi junction photovoltaic cell.
